(19) United States
(12) Patent Application Publication
(10) Pub. No.: US 2025/0359421 A1
(43) Pub. Date: Nov. 20, 2025

(54) DISPLAY DEVICE AND ELECTRONIC DEVICE

(71) Applicant: SAMSUNG DISPLAY CO., LTD., YONGIN-SI (KR)

(72) Inventors: JEONGJIN PARK, Yongin-si (KR); YONG MUN KIM, Hwaseong-si (KR); HYEONGRYEOL YOON, Hwaseong-si (KR); CHAN KOO LEE, Hwaseong-si (KR); BYUNGHOON KIM, Yongin-si (KR); TAEOH KIM, Yongin-si (KR)

(21) Appl. No.: 19/097,360

(22) Filed: Apr. 1, 2025

(30) Foreign Application Priority Data
May 14, 2024 (KR) 10-2024-0063407

(51) Int. Cl. H10H 29/85

(52) U.S. Cl. CPC H10H 29/857

(57) ABSTRACT

A display device includes a base layer including a plurality of pad electrodes exposed through a surface of the base layer, a circuit board including a plurality of bump electrodes disposed on the base layer, and a base film in which a plurality of first grooves that expose the plurality of bump electrodes through the surface of the base layer are defined. The display device further includes a plurality of metal patterns electrically connecting the plurality of pad electrodes and the plurality of bump electrodes. Each of the plurality of metal patterns includes a first part disposed in the plurality of first grooves, and a second part disposed on the plurality of pad electrodes.

### CROSS-REFERENCE TO RELATED APPLICATIONS

This application claims priority under 35 U.S.C. § 119 to Korean Patent Application No. 10-2024-0063407, filed on May 14, 2024, the disclosure of which is incorporated by reference herein in its entirety.

### TECHNICAL FIELD

Embodiments of the present disclosure relate to a display device and an electronic device, and more particularly, to a display device and an electronic device having increased reliability.

### DISCUSSION OF RELATED ART

Electronic devices, such as, for example, smartphones, tablets, notebook computers, car navigation systems, smart televisions, etc., typically include a display device that provides information to a user. Display devices may be configured using different interfaces to satisfy the needs of a particular implementation, and may include a large display area and a small non-display area.

### SUMMARY

Embodiments of the present disclosure provide a display device having a reduced non-display area, and an electronic device including the display device.

According to an embodiment, a display device includes a base layer including a plurality of pad electrodes exposed through a surface of the base layer, a circuit board including a plurality of bump electrodes disposed on the base layer, and a base film in which a plurality of grooves that expose the plurality of bump electrodes through the surface of the base layer are defined. The display device further includes a plurality of metal patterns electrically connecting the plurality of pad electrodes and the plurality of bump electrodes. Each of the plurality of metal patterns includes a first part disposed in the plurality of first grooves, and a second part disposed on the plurality of pad electrodes.

In an embodiment, the base layer includes a first sub-base layer in which a plurality of recessed parts are defined, and in which the plurality of pad electrodes are disposed in the plurality of recessed parts. The base layer further includes a second sub-base layer, in which a plurality of second grooves that expose the plurality of pad electrodes are defined.

In an embodiment, the second part is disposed in the plurality of second grooves.

In an embodiment, the second sub-base layer includes an inner surface that defines the plurality of second grooves, and the second part contacts the inner surface.

In an embodiment, the base film includes an inner surface that defines the plurality of first grooves, and the first part contacts the inner surface.

In an embodiment, a width of each of the plurality of first grooves is about equal to a width of each of the plurality of second grooves.

In an embodiment, a depth of each of the plurality of first grooves in a thickness direction of the second sub-base layer is about equal to a depth of each of the plurality of second grooves in the thickness direction.

In an embodiment, the base film is disposed directly on the second sub-base layer.

In an embodiment, the display device further includes an adhesion layer disposed between the base film and the second sub-base layer.

In an embodiment, a plurality of recessed parts, in which the plurality of pad electrodes are disposed, are defined in the base layer, and a depth of each of the plurality of recessed parts is greater than a thickness of each of the plurality of pad electrodes.

In an embodiment, each of the plurality of bump electrodes includes a protrusion that protrudes toward the plurality of recessed parts, and each protrusion contacts an inner surface that defines a corresponding one of the plurality of recessed parts.

In an embodiment, each protrusion directly contacts a corresponding one of the plurality of pad electrodes.

In an embodiment, the first part is disposed in the plurality of grooves, and the second part is disposed in the plurality of recessed parts.

In an embodiment, the second part contacts an inner surface that defines the plurality of recessed parts.

In an embodiment, the display device further includes a circuit layer disposed on the base layer, and including at least one signal line electrically connected to at least one of the pad electrodes.

According to an embodiment, a display device includes a base layer including a plurality of pad electrodes exposed through a surface of the base layer, and in which a plurality of recessed parts, in which the plurality of pad electrodes are disposed, are defined in the base layer. The display device further includes a circuit board including a plurality of bump electrodes disposed on the base layer, and a base film disposed on the plurality of bump electrodes, and a plurality of metal patterns electrically connecting the plurality of pad electrodes and the plurality of bump electrodes, and disposed in the plurality of recessed parts. Each of the plurality of bump electrodes includes a protrusion that protrudes toward a corresponding one of the plurality of recessed parts.

In an embodiment, a depth of each of the plurality of recessed parts is greater than a thickness of each of the plurality of pad electrodes, and the protrusion contacts an inner surface that defines the plurality of recessed parts.

In an embodiment, a plurality of first grooves that expose the plurality of bump electrodes through the surface of the base layer are defined in the base film.

In an embodiment, each of the plurality of metal patterns includes a first part disposed in the plurality of first grooves, and a second part disposed in the plurality of recessed parts.

According to an embodiment, an electronic device includes a housing, an electronic module disposed inside the housing, and a display device that overlaps the electronic module. The display device includes a base layer including a plurality of pad electrodes exposed through a surface of the base layer, a circuit board including a plurality of bump electrodes disposed on the base layer, and a base film in which a plurality of grooves that expose the plurality of bump electrodes through the surface of the base layer are defined. The electronic device further includes a plurality of metal patterns electrically connecting the plurality of pad electrodes and the plurality of bump electrodes. Each of the plurality of metal patterns includes a first part disposed on the plurality of bump electrodes, and a second part disposed on the plurality of pad electrodes.

According to an embodiment, a smartphone includes a housing, an electronic module disposed inside the housing, and a display device that overlaps the electronic module. The display device includes a base layer including a plurality of pad electrodes exposed through a surface of the base layer, a circuit board including a plurality of bump electrodes disposed on the base layer, and a base film in which a plurality of grooves that expose the plurality of bump electrodes through the surface of the base layer are defined. The electronic device further includes a plurality of metal patterns electrically connecting the plurality of pad electrodes and the plurality of bump electrodes. Each of the plurality of metal patterns includes a first part disposed on the plurality of bump electrodes, and a second part disposed on the plurality of pad electrodes.

### BRIEF DESCRIPTION OF THE DRAWINGS

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of an electronic device according to an embodiment of the present disclosure.

FIG. 3 is a cross-sectional view of a display device, taken along line I-I′ of FIG. 2.

FIG. 4 is a cross-sectional view of a display module according to an embodiment of the present disclosure.

FIG. 5 is a plan view of a display panel according to an embodiment of the present disclosure.

FIG. 6 is a cross-sectional view of a display module according to an embodiment of the present disclosure.

FIG. 7 is a plan view of a display panel according to an embodiment of the present disclosure.

FIG. 8 is an enlarged view of a portion of a display device according to an embodiment of the present disclosure.

FIG. 9A is a cross-sectional view of a display device, taken along line II-II′ of FIG. 8.

FIG. 9B is an enlarged view of area AA′ illustrated in FIG. 9A.

FIG. 10A is a cross-sectional view of a display device, taken along line III-III′ of FIG. 8.

FIG. 10B is a cross-sectional view of a display device, taken along line IV-IV′ of FIG. 8.

FIG. 10C is a cross-sectional view of a display device, taken along line V-V′ of FIG. 8.

FIG. 11 is an enlarged view of a portion of a display device according to an embodiment of the present disclosure.

FIG. 12A is an enlarged cross-sectional view of a portion of a display device according to an embodiment of the present disclosure.

FIG. 12B is a cross-sectional view of a display device, taken along line VI-VI′ of FIG. 11.

FIG. 12C is a cross-sectional view of a display device, taken along line VII-VII′ of FIG. 8.

FIG. 12D is a cross-sectional view of a display device, taken along line VIII-VIII′ of FIG. 8.

FIG. 13 is an enlarged view of a portion of a display device according to an embodiment of the present disclosure.

FIG. 14A is an enlarged cross-sectional view of a portion of a display device according to an embodiment of the present disclosure.

FIG. 14B is a cross-sectional view of a display device, taken along line IX-IX′ of FIG. 13.

FIG. 14C is a cross-sectional view of a display device, taken along line X-X′ of FIG. 13.

FIG. 15 is a perspective view of a laser irradiating device used to manufacture a display device according to an embodiment of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

The term “and/or” includes one or more combinations that may be defined by the associated components.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

The terms of a singular form may include plural forms unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

When terms such as, for example, “comprise” and/or “comprising”, are used in the specification, it should be understood that they specify the presence of the associated features, numbers, steps, operations, components, parts, and/or combinations thereof, and do not exclude the presence or addition of one or more other numbers, steps, operations, components, parts, and/or combinations thereof.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Embodiments of the present disclosure relate to a display device that can reduce non-display areas while ensuring reliable electrical connections and durability. The display device may include a layered structure with pad electrodes and bump electrodes that are connected by metal patterns arranged in a unique way. Embodiments may utilize a base layer with a plurality of grooves, exposing bump electrodes to the outside, and a base film. Metal patterns may be disposed placed within these grooves to connect the electrodes and maintain alignment and insulation, which may prevents short-circuiting and improve the stability of the electrical connection. A display device according to embodiments of the present application can be integrated within an electronic device housing, overlapping other internal modules, resulting in a more compact and efficient design having improved durability and reliability by preventing potential electrical and alignment issues.

Embodiments of the present disclosure provide a display device including a base film with multiple grooves, each containing bump electrodes. Metal patterns that connect the bump electrodes may be positioned within these grooves, allowing the patterns to be insulated from one another. This configuration may prevent electrical failures due to short-circuiting between the metal patterns. In addition, placing the bump electrodes within the grooves may prevent them from bending in one direction during the attachment of the circuit board to the back of the display panel. This arrangement may reduce the likelihood of defects caused by misalignment between the bump electrodes and pad electrodes.

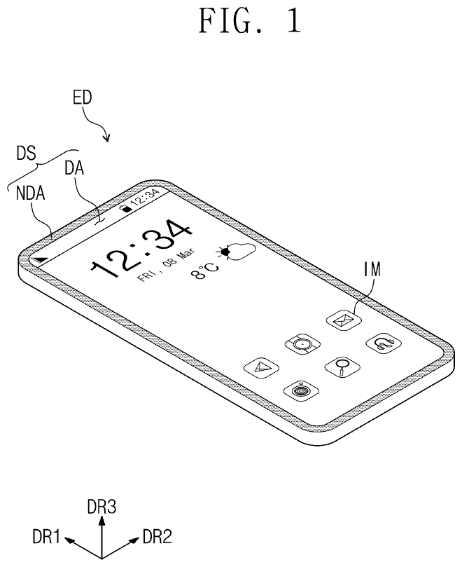

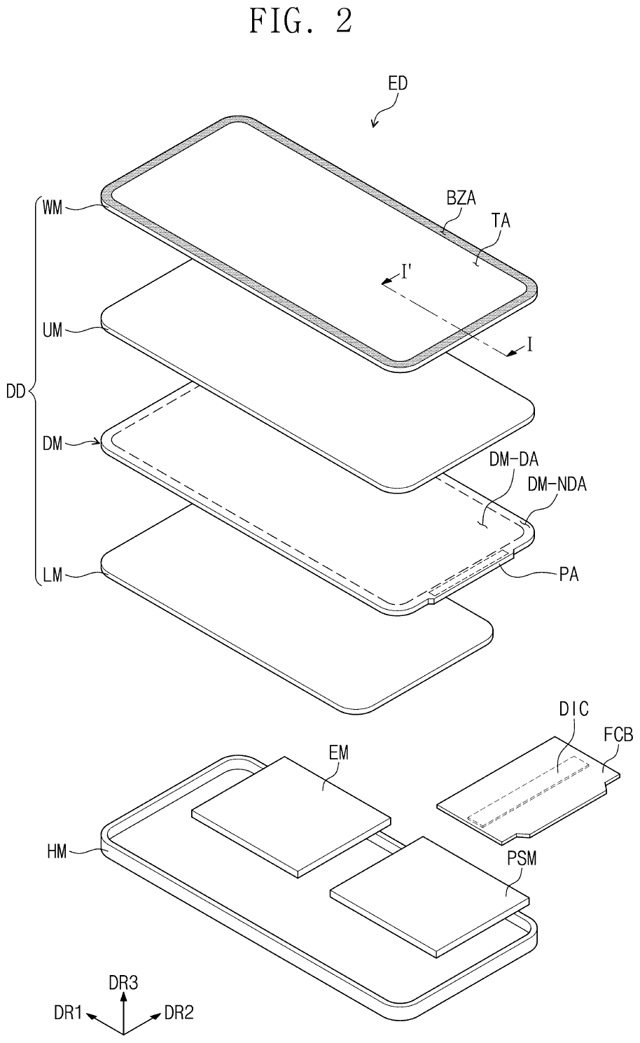

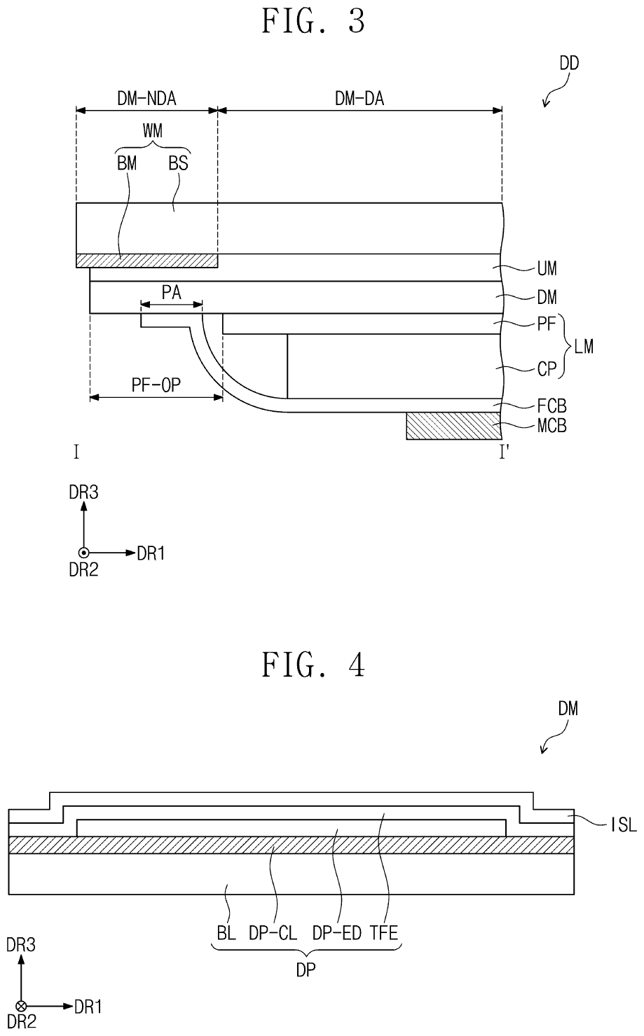

FIG. 1 is a perspective view of an electronic device according to an embodiment of the present disclosure. FIG. 2 is an exploded perspective view of an electronic device according to an embodiment of the present disclosure. FIG. 3 is a cross-sectional view of a display device, taken along line I-I′ of FIG. 2.

Referring to FIG. 1, an electronic device ED according to an embodiment of the present disclosure may include a display surface DS that is defined by a first direction DR1, and a second direction DR2 that crosses the first direction DR1. The electronic device ED may provide an image IM to the user through a display surface DS.

The display surface DS may include a display area DA, and a non-display area NDA around the display area DA. The display area DA may be an area in which an image IM is displayed, and the non-display area NDA may be an area in which the image IM is not displayed. The non-display area NDA may surround the display area DA. However, the present disclosure is not limited thereto, and a shape of the display area DA and a shape of the non-display area NDA may be modified.

Hereinafter, a direction that substantially perpendicularly crosses a plane that is defined by the first direction DR1 and the second direction DR2 is defined as a third direction DR3. The third direction DR3 is a reference for distinguishing a front surface and a rear surface of each member. In the specification, “on a plane” may be defined as a state in which the electronic device ED is viewed from the third direction DR3.

In an embodiment of the present disclosure, the electronic device ED may be a foldable electronic device that may be folded about a folding axis. The folding axis may be parallel to the first direction DR1 or the second direction DR2, and a folding area may be defined at a portion of the display area DA. The electronic device ED may be in-folded such that the display area DA faces inward, or may out-folded such that the display area DA is positioned further away when folded. For example, as shown in FIGS. 1 and 2, the electronic device ED may be a smartphone, and the smartphone may be a foldable phone.

As illustrated in FIG. 2, the electronic device ED may include a display device DD, an electronic module EM, a power source module PSM, and a housing HM. FIG. 2 schematically illustrates the electronic device ED, and the electronic device ED may further include a mechanical structure (e.g., a hinge) for controlling an operation (e.g., folding or rolling) of the display device DD.

The display device DD generates an image IM and detects an external input. The display device DD includes a window WM, an upper member UM, a display module DM, a lower member LM, a circuit board (or a flexible circuit board) FCB, and a driving chip DIC. The upper member UM includes members that are disposed on an upper side of the display module DM, and the lower member LM includes members that are disposed on a lower side of the display module DM.

The window WM provides a front surface of the electronic device ED. The window WM includes a transmission area TA and a bezel area BZA. The display area DA and the non-display area NDA of the display surface DS illustrated in FIG. 1 are defined by the transmission area TA and the bezel area BZA. The transmission area TA is an area through which an image passes, and the bezel area BZA is an area that covers a structure/member that is disposed on a lower side of the window WM.

The display module DM includes a display area DM-DA and a non-display area DM-NDA corresponding to the display area DA and the non-display area NDA illustrated in FIG. 1. In the specification, “an area/part corresponds to another area/part” means overlapping, and is not limited to the same extent.

A pad area PA is disposed on one side of the non-display area DM-NDA. The pad area PA is an area that is electrically bonded (or connected) to the circuit board FCB, which will be described below. In an embodiment, the pad area PA is defined on a rear surface of the display module DM.

The display module DM has a substantially rectangular shape. The term “substantially rectangular shape” encompasses not only a mathematically defined rectangle but also any shape that resembles a rectangle as recognized by the user. For example, this can include rectangles with rounded corners. Additionally, the edges of the display module DM are not restricted to being straight; they may also have curved sections.

The upper member UM may include a protective film or an optical film. The optical film may include a polarizer and a retarder which may reduce reflection of external light. The lower member LM may include a protective film that protects the display module DM, a support member that supports the display module DM, and a digitizer. A detailed description of the upper member UM and the lower member LM is provided below.

The circuit board FCB is disposed on a lower side of the display module DM. The circuit board FCB may be bonded to a rear surface of the display module DM. The circuit board FCB electrically connects the display module DM and a main circuit board MCB (see FIG. 3). The circuit board FCB includes at least one insulating layer and at least one conductive layer. The conductive layer may include a plurality of signal lines.

The driving chip DIC may be mounted on the circuit board FCB. The driving chip DIC may include a driving circuit, for example, a data driving circuit that drives pixels of the display module DM. Although FIG. 2 illustrates a structure in which the driving chip DIC is mounted on the circuit board FCB, the present disclosure is not limited thereto. For example, the driving chip DIC may be mounted on the display module DM or the main circuit board according to embodiments.

The electronic module EM may include, for example, a control module, a wireless communication module, an image input module, a sound input module, a sound output module, a memory, and an external interface module. The electronic module EM may include a main circuit board, and the modules may be mounted on the main circuit board or electrically connected to the main circuit board through a flexible circuit board. The electronic module EM is electrically connected to the power source module PSM.

According to embodiments, the electronic device ED may further include an electronic optical module. The electronic optical module may be an electronic component that outputs or receives an optical signal. The electronic optical module may include a camera module and/or a proximity sensor. The camera module may capture an external image through a partial area of the display module DM.

The housing HM illustrated in FIG. 2 is coupled to the display device DD, for example, to the window WM, and accommodates the other modules. Although it is illustrated that the housing HM has an integral shape, the present disclosure is not limited thereto. For example, according to embodiments, the housing HM may include a plurality of parts (e.g., a side peripheral part and a bottom part) that are coupled to each other.

Referring to FIG. 3, the window WM may include a base substrate BS, and a bezel pattern BM that is disposed on a lower surface of the base substrate BS. The base substrate BS may include a synthetic resin film or a glass substrate. The base substrate BS may have a multi-layer structure. The base substrate BS may include a thin film glass substrate, a protective film that is disposed on the thin film glass substrate, and an adhesion layer that couples the thin film glass substrate and the protective film.

The bezel pattern BM is a colored light shielding film, and may be formed, for example, through a coating method. The bezel pattern BM may include a base material, and a dye or a pigment that is mixed into the base material. The bezel pattern BM overlaps the non-display area NDA illustrated in FIG. 1 and the bezel area BZA illustrated in FIG. 2. The bezel pattern BM may be disposed on a lower surface of the base substrate BS. When the base substrate BS has a multi-layer structure, the bezel pattern BM may be disposed between interfaces that are defined by a plurality of layers. For example, the bezel pattern BM may be disposed between a thin film glass substrate and a protective film. The window WM may further include at least one of, for example, a hard coating layer, an anti-fingerprint layer, and an anti-reflection layer, disposed on an upper surface of the base substrate BS.

The upper member UM may include an upper film. The upper film may include a synthetic resin film. The synthetic resin film may include, for example, polyimide, polycarbonate, polyamide, triacetylcellulose, polymethylmethacrylate, or polyethylene terephthalate.

The upper film may absorb an external impact that is applied to a front surface of the display device DD. In an embodiment of the present disclosure, the display module DM may include a color filter that replaces a polarizing film as a reflection preventing member, and accordingly, an impact strength of the front surface of the display device DD may be reduced. The upper film may compensate for the reduced impact strength by applying the color filter.

The upper member UM overlaps the bezel area BZA (see FIG. 2) and the transmission area TA (see FIG. 2). The upper member UM may overlap only a partial area of the bezel area BZA. A portion of the bezel pattern BM may be exposed from the upper member UM. In an embodiment of the present disclosure, the upper member UM may be omitted. In an embodiment of the present disclosure, the upper member UM may be replaced with an optical film including a polarizer and a retarder.

In an embodiment, an adhesion layer may be further included between the upper member UM and the window WM to couple the upper member UM and the window WM. The adhesion layer may be, for example, a pressure sensitive adhesive film (PSA) or an optically clear adhesive (OCA).

The display module DM is disposed on a lower side of the upper member UM. The display module DM overlaps the bezel area BZA (see FIG. 2) and the transmission area TA (see FIG. 2). The display module DM may completely overlap the upper member UM in the bezel area BZA. A side surface of the display module DM may be aligned with a side surface of the upper member UM, and corners of the display module DM on a plane may be aligned with corners of the upper member UM.

The pad area PA of the display module DM may overlap the upper member UM in the bezel area BZA. A portion of the display module DM corresponding to the pad area PA may be coupled to a lower surface of the upper member UM by an adhesion layer. When the pad area PA overlaps the upper member UM, and a portion of the pad area PA of the display module DM, which overlaps the upper member UM, is coupled to the upper member UM, the upper member UM may sufficiently support the pad area PA when the circuit board FCB is bonded to the pad area PA.

The lower member LM may include a lower film PF and a cover panel CP. In an embodiment of the present disclosure, the lower member LM may further include a support plate and a digitizer.

The lower film PF may expose the pad area PA of the display module DM. The lower film PF may have a smaller size than that of the display module DM. In an embodiment, the lower film PF may overlap only the display area DM-DA of the display module DM. An open area PF-OP corresponding to the non-display area DM-NDA may be defined in the lower film PF. In an embodiment, the lower film PF may have a size substantially corresponding to the display module DM. In this case, an open area PF-OP corresponding to the pad area PA may be defined in the lower film PF. The pad area PA may be exposed through the open area PF-OP.

A cover panel CP may be disposed on a lower side of the lower film PF. The cover panel CP may increase a resistance to a compressive force generated by external pressing. Accordingly, the cover panel CP may serve to prevent deformation of the display module DM. The cover panel CP may include a flexible plastic material, such as, for example, polyimide or polyethylene terephthalate. In addition, the cover panel CP may be a colored film with a low light transmittance. The cover panel CP may absorb light that is input from outside of the display device DD. For example, the cover panel CP may be a black synthetic resin film. When the display device DD is viewed from an upper side of the window WM, the components disposed on a lower side of the cover panel CP may not be visually recognized by the user.

In an embodiment, a support plate may be further disposed on a lower side of the cover panel CP. The support plate may include a high-strength metal material. The support plate may include a reinforced fiber composite. The support plate may include reinforced fibers that are disposed on an inner side of the matrix part. The reinforced fibers may be carbon fibers or glass fibers. The matrix part may include a polymer resin. The matrix part may include a thermoplastic resin. For example, the matrix part may include a polyamide-based resin or a polypropylene-based resin. For example, the reinforced fiber composite may be carbon fiber reinforced plastic (CFRP) or glass fiber reinforced plastic (GFRP).

A main circuit board MCB may be disposed on a lower surface of the circuit board FCB. The circuit board FCB may include an insulating film, and conductive wiring lines that are mounted on the insulating film. The main circuit board MCB may include signal lines and electronic elements. The electronic elements may be connected to the signal lines, and may be electrically connected to the display module DM. The electronic elements generate various electrical signals, for example, signals for generating images, or signals for detecting external inputs, or process detected signals. The main circuit board MCB may be configured in different ways: a single MCB can handle each electrical signal that is to be generated and processed, or multiple MCBs (three or more) can be used. This disclosure does not limit the design to any specific configuration.

The main circuit board MCB may include a driving chip DIC (see FIG. 2) that is mounted in the main circuit board MCB.

Referring to FIGS. 2 and 3, a circuit board FCB is coupled to a rear surface of the display module DM (back bonding). Because the non-display area DM-NDA of the display module DM is not bent, a defect that occurs when the non-display area DM-NDA of the display module DM is bent may be prevented. Furthermore, an extent of the bezel area BZA of the window WM for covering the non-display area DM-NDA of the display module DM may be reduced.

FIG. 4 is a cross-sectional view of a display module according to an embodiment of the present disclosure.

Referring to FIG. 4, the display module DM may include a display panel DP and an input sensing layer ISL. The display panel DP may include a base layer BL, a circuit layer DP-CL, a display element layer DP-ED, and an encapsulation layer TFE.

The circuit layer DP-CL is disposed on an upper surface of the base layer BL. The base layer BL may be a flexible substrate that may be bent, folded, or rolled. The base layer BL may be, for example, a glass substrate, a metal substrate, a polymer substrate, and the like. However, the present disclosure is not limited thereto. For example, according to embodiments, the base layer BL may be an inorganic layer, an organic layer, or a composite material layer. The base layer BL may have substantially the same shape as that of the display panel DP.

The base layer BL may have a multi-layer structure. For example, the base layer BL may include a first synthetic resin layer, a second synthetic resin layer, and inorganic layers that are disposed therebetween. Each of the first and second synthetic resin layers may include a polyimide-based resin, and is not particularly limited.

The circuit layer DP-CL may be disposed on the base layer BL. The circuit layer DP-CL may include a plurality of insulating layers, a plurality of semiconductor patterns, a plurality of conductive patterns, and signal lines. The circuit layer DP-CL may include a driving circuit of a pixel. Hereinafter, unless otherwise specified, when configuration “A” and configuration “B” are disposed on the same layer, it is construed that they are formed through the same process and include the same material or have the same lamination structure. The conductive patterns or semiconductor patterns that are disposed on the same layer may be construed as described above.

The display element layer DP-ED may be disposed on the circuit layer DP-CL. The display element layer DP-ED may include a light emitting element. For example, the light emitting element may include an organic light emitting material, an inorganic light emitting material, an organic-inorganic light emitting material, quantum dots, quantum rods, a micro LED, or a nano LED.

The encapsulation layer TFE may be disposed on the display element layer DP-ED. The encapsulation layer TFE may protect the display element layer DP-ED, that is, the light emitting element, from foreign substances, such as moisture, oxygen, and dust particles. The encapsulation layer TFE may include at least one encapsulation inorganic layer. The encapsulation layer TFE may include a lamination structure of a first encapsulation inorganic layer, an encapsulation organic layer, and a second encapsulation inorganic layer.

The input sensing layer ISL may be disposed directly on the display panel DP. The input sensing layer ISL may detect an input by the user, for example, through an electromagnetic induction method or a capacitive method. The display panel DP and the input sensing layer ISL may be formed through a continuous process. Here, “directly disposed” may mean that no third component is disposed between the input sensing layer ISL and the display panel DP. For example, in an embodiment, a separate adhesion layer is not disposed between the input sensing layer ISL and the display panel DP.

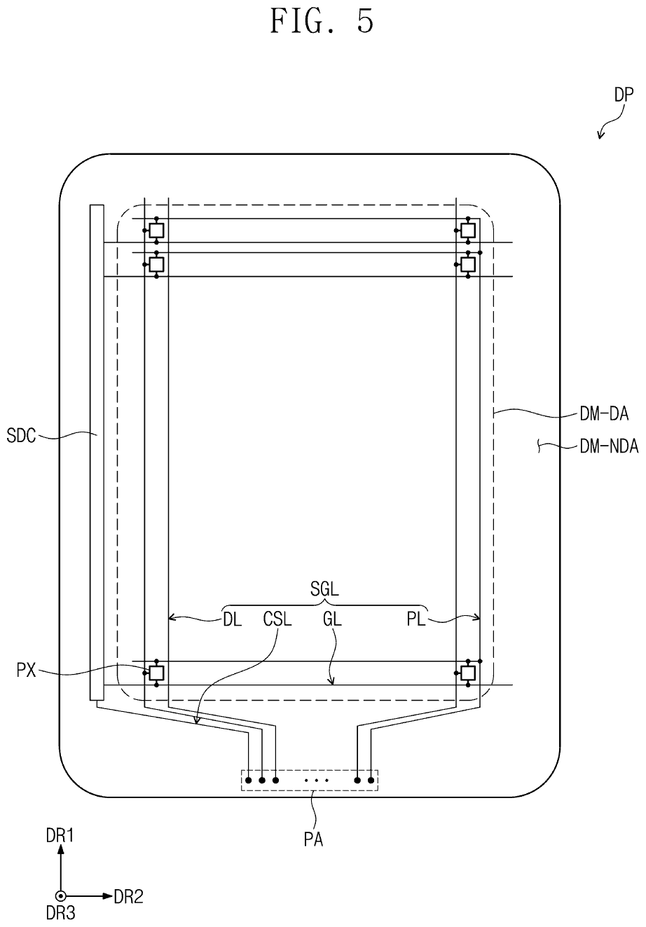

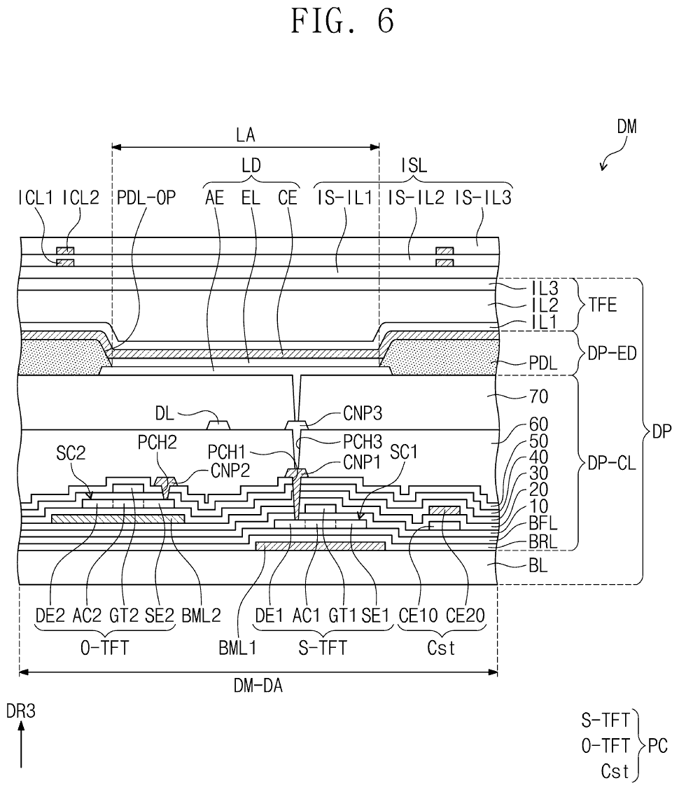

FIG. 5 is a plan view of a display panel according to an embodiment of the present disclosure. FIG. 6 is a cross-sectional view of a display module according to an embodiment of the present disclosure.

As illustrated in FIG. 5, the display panel DP may include a scan driving circuit SDC, a plurality of signal lines SGL, and a plurality of pixels PX. The plurality of pixels PX are disposed in a display area DM-DA. Each of the pixels PX includes a light emitting element and a pixel driving circuit connected thereto. The scan driving circuit SDC, the plurality of signal lines SGL, and the pixel driving circuit may be included in a circuit layer DP-CL illustrated in FIG. 4.

The scan driving circuit SDC may include a gate driving circuit. The gate driving circuit generates a plurality of scan signals, and sequentially outputs the plurality of scan signals to a plurality of scan lines GL that will be described below. The scan driving circuit SDC may further include a light emission driving circuit that is distinct from the gate driving circuit. The light emission driving circuit may output scan signals to another group of scan lines.

The scan driving circuit SDC may include a plurality of thin film transistors formed through the same process as that of the pixel driving circuit, for example, a low temperature polycrystalline silicon (LTPS) process or a low temperature polycrystalline oxide (LTPO) process.

The plurality of signal lines SGL include scan lines GL, data lines DL, a power line PL, and a control signal line CSL. Each of the scan lines GL is connected to a corresponding one of the plurality of pixels PX, and each of the data lines DL is connected to a corresponding one of the plurality of pixels PX. The power line PL is connected to the plurality of pixels PX. The data lines DL provide data signals to the pixels PX. The control signal line CSL may provide control signals to the scan driving circuit SDC.

A plurality of power lines PL may be provided. For example, a power line PL may include a first power line that receives a first power voltage and a second power line that receives a second power voltage having a higher level than the first power voltage. The first power voltage is provided to the pixel PX through the first power line, and the second power voltage is provided to the pixels PX through the second power line. In FIG. 5, for convenience of illustration, one control signal line CSL is illustrated as an example, but a plurality of control signal lines CSL may be provided.

The scan lines GL, the data lines DL, and the power line PL may overlap the display area DM-DA and the non-display area DM-NDA, and the control signal line CSL may overlap the non-display area DM-NDA. Distal ends of the multiple signal lines SGL may be aligned on one side of the non-display area DM-NDA. Each of the plurality of signal lines SGL may have an integral shape, but may include a plurality of parts that are disposed on different layers. The different parts, which are divided by the insulating layer, may be connected through a contact hole that passes through the insulating layer. For example, the data lines DL may include a first part that is disposed in the display area DM-DA and a second part that is disposed in the non-display area DM-NDA and is disposed on a different layer from the first part. The first part and the second part may include different materials and have different lamination structures.

The plurality of signal lines SGL may be electrically connected to the main circuit board MCB illustrated in FIG. 3 through the pad area PA.

FIG. 6 illustrates a cross-section of the display module DM corresponding to a pixel PX of FIG. 5.

A pixel driving circuit PC that drives a light emitting element LD may include a plurality of pixel driving elements. The pixel driving circuit PC may include a plurality of transistors S-TFT and O-TFT and a capacitor Cst. The plurality of transistors S-TFT and O-TFT may include a silicon transistor S-TFT and an oxide transistor O-TFT. In FIG. 6, the silicon transistor S-TFT and the oxide transistor O-TFT are illustrated as examples. It is to be understood that the pixel driving circuit PC of FIG. 6 is merely an embodiment, and the configuration of the pixel driving circuit PC is not necessarily limited thereto. The pixel driving circuit PC may include only one type of transistor among the silicon transistor S-TFT and the oxide transistor O-TFT.

Referring to FIG. 6, the base layer BL is illustrated as a single layer. The base layer BL may include a synthetic resin, such as, for example, polyimide. The base layer BL may be formed by coating a synthetic resin layer on a work substrate (or a carrier substrate). When the display module DM is completed by performing the subsequent process, the work substrate may be removed.

A first shield electrode BML1 may be disposed on a base layer BL. The first shield electrode BML1 may receive a bias voltage. The first shield electrode BML1 may also receive a first power voltage. The first shield electrode BML1 may prevent an electric potential due to a polarization phenomenon from affecting a silicon transistor S-TFT. The first shield electrode BML1 may prevent external light from reaching the silicon transistor S-TFT. In an embodiment of the present disclosure, the first shield electrode BML1 may be a floating electrode that is isolated from the other electrodes or wiring lines. The first shield electrode BML1 may be disposed to correspond to the silicon transistor S-TFT. The first shield electrode BML1 may include a metal, for example, molybdenum.

A barrier layer BRL may be disposed on the base layer BL and the first shield electrode BML1. The barrier layer BRL prevents foreign substances from being introduced from outside of the display device DD. The barrier layer BRL may include at least one inorganic layer. The barrier layer BRL may include a silicon oxide layer and a silicon nitride layer. The silicon oxide layer and the silicon nitride layer may be provided in plural, and may be alternately laminated.

A buffer layer BFL may be disposed on the barrier layer BRL. The buffer layer BFL may prevent metal atoms or impurities from diffusing from the base layer BL to a first semiconductor pattern SC1 on an upper side. The buffer layer BFL may include at least one inorganic layer. The buffer layer BFL may include a silicon oxide layer and a silicon nitride layer.

A first semiconductor pattern SC1 may be disposed on the buffer layer BFL. The first semiconductor pattern SC1 may include a silicon semiconductor. For example, the silicon semiconductor may include amorphous silicon, polycrystalline silicon, and the like. For example, the first semiconductor pattern SC1 may include low-temperature polysilicon.

The first semiconductor pattern SC1 may have different electrical properties depending on whether it is doped. The first semiconductor pattern SC1 may include a first area having a high conductivity and a second area having a low conductivity. The first area may be doped with an N-type dopant or a P-type dopant. A P-type transistor may include a doped area that is doped with a P-type dopant, and an N-type transistor may include a doped area that is doped with an N-type dopant. The second area may be an undoped area or an area that is doped at a lower concentration than that of the first area. In an embodiment, the first semiconductor pattern SC1 may be an N-type transistor.

A conductivity of the first area is greater than that of the second area, and the first area may substantially serve as an electrode or a signal line. The second area may correspond substantially to a channel area (or an active area) of the transistor. In other words, a portion of the first semiconductor pattern SC1 may be the channel of the transistor, another portion thereof may be the source or drain of the transistor, and another portion thereof may be the connection electrode or the connection signal line.

A source area SE1, a channel area AC1 (or active area), and a drain area DE1 of the silicon transistor S-TFT may be formed from the first semiconductor pattern SC1. The source area SE1 and the drain area DE1 may extend in opposite directions from the channel area AC1 on a cross-section.

A first insulating layer 10 may be disposed on a buffer layer BFL. The first insulating layer 10 may cover the first semiconductor pattern SC1. The first insulating layer 10 may be an inorganic layer. The first insulating layer 10 may be a single-layer silicon oxide layer. The inorganic layer of the circuit layer DP-CL, which will be described below, as well as the first insulating layer 10, may have a single-layer or multi-layer structure, and may include at least one of the materials described above, but is not limited thereto.

A gate (or a gate electrode) GT1 of a silicon transistor S-TFT is disposed on the first insulating layer 10. The gate GT1 may be a part of a metal pattern. The gate GT1 overlaps the channel area AC1. In a process of doping the first semiconductor pattern SC1, the gate GT1 may be a mask. A first electrode CE10 of a storage capacitor Cst is disposed on the first insulating layer 10. Unlike the illustration of FIG. 6, the first electrode CE10 may have an integral shape with the gate GT1.

A second insulating layer 20 is disposed on the first insulating layer 10, and may cover the gate GT1. In an embodiment of the present disclosure, an upper electrode that overlaps the gate GT1 may be further disposed on the second insulating layer 20. A second electrode CE20 that overlaps the first electrode CE10 may be disposed on the second insulating layer 20. The upper electrode may have an integral shape with the second electrode CE20 on a plane.

A second shield electrode BML2 is disposed on the second insulating layer 20. The second shield electrode BML2 may be disposed to correspond to an oxide transistor O-TFT. In an embodiment of the present disclosure, the second shield electrode BML2 may be omitted. According to an embodiment of the present disclosure, the first shield electrode BML1 may extend to a lower portion of the oxide transistor O-TFT, and may replace the second shield electrode BML2.

A third insulating layer 30 may be disposed on the second insulating layer 20. A second semiconductor pattern SC2 may be disposed on the third insulating layer 30. The second semiconductor pattern SC2 may include a channel area AC2 of the oxide transistor O-TFT. The second semiconductor pattern SC2 may include a metal oxide semiconductor. The second semiconductor pattern SC2 may include a transparent conductive oxide (TCO) such as, for example, indium tin oxide (ITO), indium zinc oxide (IZO), indium gallium zinc oxide (IGZO), zinc oxide (ZnOx), or indium oxide (In2O3).

The metal oxide semiconductor may include several areas—SE2, AC2, and DE2—that are differentiated based on whether the transparent conductive oxide has been reduced. An area where the transparent conductive oxide is reduced (referred to as a “reduced area”) has higher conductivity than an area where it is not reduced (referred to as a “non-reduced area”) . . . . The reduced area serves as a source/drain or a signal line of the transistor, and the non-reduced area corresponds to the semiconductor area (or a channel) of the transistor. In other words, a partial area of the second semiconductor pattern SC2 may be a semiconductor area of the transistor, another partial area may be a source area SE2/drain area DE2 of the transistor, and another partial area may be a signal transmission area.

A fourth insulating layer 40 may be disposed on the third insulating layer 30. As illustrated in FIG. 6, the fourth insulating layer 40 may cover the second semiconductor pattern SC2. In an embodiment of the present disclosure, the fourth insulating layer 40 may be an insulating pattern that overlaps a gate GT2 of the oxide transistor O-TFT and exposes the source area SE2 and the drain area DE2 of the oxide transistor O-TFT.

A gate GT2 of the oxide transistor O-TFT is disposed on the fourth insulating layer 40. The gate GT2 of the oxide transistor O-TFT may be a part of a metal pattern. The gate GT2 of the oxide transistor O-TFT overlaps the channel area AC2.

A fifth insulating layer 50 is disposed on the fourth insulating layer 40, and the fifth insulating layer 50 may cover the gate GT2. Each of the first insulating layer 10 to the fifth insulating layer 50 may be an inorganic layer.

A conductive layer may be disposed on the fifth insulating layer 50. In an embodiment, the conductive layer may include a first connection pattern CNP1 and a second connection pattern CNP2. Because the first connection pattern CNP1 and the second connection pattern CNP2 are formed through the same process, they may have the same material and the same lamination structure. The first connection pattern CNP1 may be connected to the drain area DE1 of the silicon transistor S-TFT through a first pixel contact hole PCH1 that passes the first to fifth insulating layers 10, 20, 30, 40, and 50. The second connection pattern CNP2 may be connected to the source area SE2 of the oxide transistor O-TFT through a second pixel contact hole PCH2 that passes the fourth and fifth insulating layers 40 and 50. A connection relationship of the first connection pattern CNP1 and the second connection pattern CNP2 for the silicon transistor S-TFT and the oxide transistor O-TFT is not necessarily limited thereto.

A sixth insulating layer 60 may be disposed on the fifth insulating layer 50. A third connection pattern CNP3 may be disposed on the sixth insulating layer 60. The third connection pattern CNP3 may be connected to the first connection pattern CNP1 through a third pixel contact hole PCH3 that passes through the sixth insulating layer 60. A data line DL may be disposed on the sixth insulating layer 60. A seventh insulating layer 70 is disposed on the sixth insulating layer 60, and may cover the third connection pattern CNP3 and the data line DL. Because the third connection pattern CNP3 and the data line DL are formed through the same process, they may have the same material and the same lamination structure. Each of the sixth insulating layer 60 and the seventh insulating layer 70 may be an organic layer.

The first shield electrode BML1, the gate GT1 of the silicon transistor S-TFT, the second electrode CE20, and the gate GT2 of the oxide transistor O-TFT may include molybdenum (Mo) having a high heat resistance, an alloy containing molybdenum, titanium (Ti), or an alloy containing titanium. The first connection pattern CNP1 and the second connection pattern CNP2 may include aluminum having a high electrical conductivity. The first connection pattern CNP1 and the second connection pattern CNP2 may have a three-layer structure, in which titanium, aluminum, and titanium are laminated.

The light emitting element LD may include an anode AE (or a first electrode), a light emission layer EL, and a cathode CE (or a second electrode). The anode AE of the light emitting element LD may be disposed on the seventh insulating layer 70. The anode AE may be a transparent electrode, a semitransparent electrode, or a reflective electrode. The anode AE may include a lamination structure of sequentially stacked ITO, Ag, and ITO. The locations of the anode AE and the cathode CE may be interchanged.

A pixel definition film PDL may be disposed on the seventh insulating layer 70. The pixel definition film PDL may be an organic layer. The pixel definition film PDL may have a property of absorbing light, and for example, the pixel definition film PDL may have a black color. The pixel definition film PDL may include a black coloring agent. The black component may include a black dye or a black pigment. The black component may include, for example, carbon black, a metal such as chromium, or an oxide thereof. The pixel definition film PDL may correspond to a light-shielding pattern having light-shielding properties.

The pixel definition film PDL may cover a portion of the anode AE. For example, an opening PDL-OP that exposes a portion of the anode AE may be defined in a pixel definition film PDL. A light emission area LA may be defined to correspond to the opening PDL-OP. In an embodiment of the present disclosure, a hole control layer may be disposed between the anode AE and the light emission layer EL. The hole control layer may include a hole transport layer, and may further include a hole injection layer. An electron control layer may be disposed between the light emission layer EL and the cathode CE. The electron control layer may include an electron transport layer, and may further include an electron injection layer.

An encapsulation layer TFE may cover a light emitting element LD. The encapsulation layer TFE may include a first encapsulation/insulation layer IL1, a second encapsulation/insulation layer IL2, and a third encapsulation/insulation layer IL3. However, the present disclosure is not limited thereto. For example, according to embodiments, the encapsulation layer TFE may further include a plurality of inorganic layers and a plurality of organic layers.

The first encapsulation/insulation layer IL1 may be an inorganic layer. The first encapsulation/insulation layer IL1 may prevent external moisture or oxygen from penetrating into the light emitting element LD. For example, the first encapsulation/insulation layer IL1 may include silicon nitride, silicon oxide, or a combined compound thereof. The first encapsulation/insulation layer IL1 may be formed through a chemical vapor deposition process.

The second encapsulation/insulation layer IL2 may be an organic layer. The second encapsulation/insulation layer IL2 may be disposed on the first encapsulation/insulation layer IL1, and may contact the first encapsulation/insulation layer IL1. The second encapsulation/insulation layer IL2 may provide a flat surface on the first encapsulation/insulation layer IL1. Curves that are formed on an upper surface of the first encapsulation/insulation layer IL1 or particles that exist on the first encapsulation/insulation layer IL1 may be covered by the second encapsulation/insulation layer IL2 whereby an influence of a surface state of an upper surface of the first encapsulation/insulation layer IL1 on the configurations that are formed on the second encapsulation/insulation layer IL2 may be prevented. Furthermore, the second encapsulation/insulation layer IL2 may alleviate stress between contacting layers. The second encapsulation/insulation layer IL2 may be formed through a solution process, such as, for example, spin coating, slit coating, or inkjet process.

The third encapsulation/insulation layer IL3 is disposed on the second encapsulation/insulation layer IL2, and covers the second encapsulation/insulation layer IL2. The third encapsulation/insulation layer IL3 may be stably formed on a relatively flat surface, compared to when it is disposed on the first encapsulation/insulation layer IL1. The third encapsulation/insulation layer IL3 may encapsulate moisture, or the like that is discharged from the second encapsulation/insulation layer IL2, and prevent the moisture from leaking.

The third encapsulation/insulation layer IL3 may be optically transparent. For example, the third encapsulation/insulation layer IL3 may have a visible light transmittance of about 90% or more. The third encapsulation/insulation layer IL3 may have a relatively high light transmittance compared to that of the first encapsulation/insulation layer IL1. The third encapsulation/insulation layer IL3 may be an inorganic layer. The third encapsulation/insulation layer IL3 may include silicon oxide (SiOx) or silicon oxynitride (SiON). The third encapsulation/insulation layer IL3 may be formed through a chemical vapor deposition process. Each of the first encapsulation/insulation layer IL1, the second encapsulation/insulation layer IL2, and the third encapsulation/insulation layer IL3 may include multiple layers.

The input sensing layer ISL may include at least one conductive layer (or at least one sensor conductive layer) and at least one insulating layer (or at least one sensor insulating layer). In an embodiment, the input sensing layer ISL may include a first insulating layer IS-IL1, a first conductive layer ICL1, a second insulating layer IS-IL2, a second conductive layer ICL2, and a third insulating layer IS-IL3. In FIG. 6, a conductive line of the first conductive layer ICL1 and a conductive line of the second conductive layer ICL2 are briefly illustrated.

The first insulating layer IS-IL1 may be disposed directly on the display panel DP. The first insulating layer IS-IL1 may be an inorganic layer including at least one of, for example, silicon nitride, silicon oxynitride, and silicon oxide. Each of the first conductive layer ICL1 and the second conductive layer ICL2 may have a single layer structure or a multi-layer structure that is laminated along the third direction DR3. The first conductive layer ICL1 and the second conductive layer ICL2 may include conductive lines that define a mesh-shaped electrode. The conductive line of the first conductive layer ICL1 and the conductive line of the second conductive layer ICL2 may or may not be connected to each other through a contact hole that passes through the second insulating layer IS-IL2. A connection relationship of the conductive line of the first conductive layer ICL1 and the conductive line of the second conductive layer ICL2 may be determined depending on a type of a sensor that is formed by the input sensing layer ISL.

The first conductive layer ICL1 and the second conductive layer ICL2 of the single layer structure may include a metal layer or a transparent conductive layer. The metal layer may include, for example, molybdenum, silver, titanium, copper, aluminum, or an alloy thereof. The transparent conductive layer may include, for example, a transparent conductive oxide, such as indium tin oxide (ITO), indium zinc oxide (IZO), zinc oxide (ZnOx), or indium zinc tin oxide (IZTO). Furthermore, the transparent conductive layer may include, for example, a conductive polymer, such as PEDOT, a metal nanowire, graphene, or the like.

The first conductive layer ICL1 and the second conductive layer ICL2 of the multi-layer structure may include metal layers. The metal layers may have a three-layer structure of, for example, titanium, aluminum, and titanium. A conductive layer of the multi-layer structure may include at least one metal layer and at least one transparent conductive layer. The second insulating layer IS-IL2 may be disposed between the first conductive layer ICL1 and the second conductive layer ICL2. The third insulating layer IS-IL3 may cover the second conductive layer ICL2. In an embodiment of the present disclosure, the third insulating layer IS-IL3 may be omitted. The second insulating layer IS-IL2 and the third insulating layer IS-IL3 may include an inorganic layer or an organic layer.

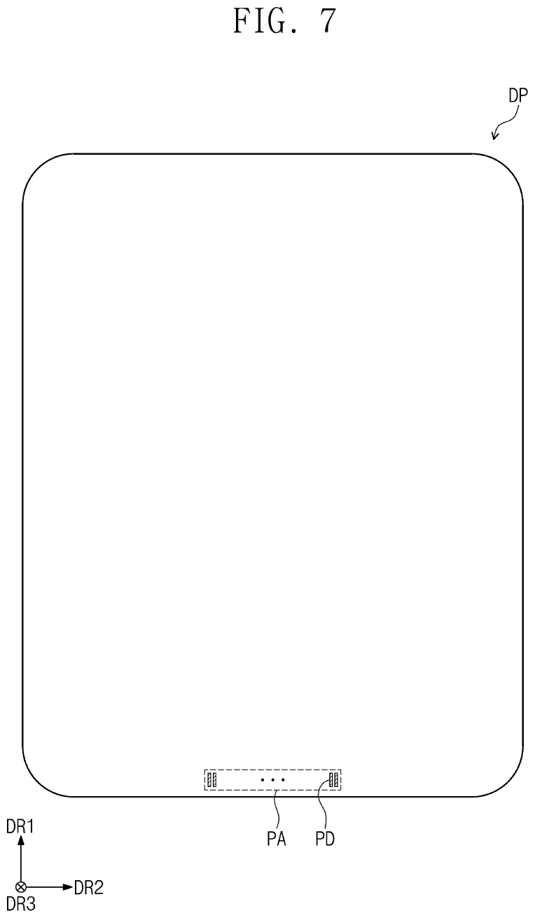

FIG. 7 is a plan view of a display panel according to an embodiment of the present disclosure. For example, FIG. 7 is a plan view of the display panel DP, when viewed from the third direction DR3.

Referring to FIG. 7, a pad electrode PD may be disposed on a rear surface of the display panel DP. For example, the pad electrode PD may be disposed in a pad area PA. A plurality of pad electrodes PD may be provided. The pad electrodes PD may be arranged in the second direction DR2.

A plurality of signal lines SGL (see FIG. 5) that are disposed on the display panel DP may be electrically connected to the circuit board FCB illustrated in FIG. 3 through the pad area PA. For example, a plurality of signal lines SGL (see FIG. 5) may be disposed on the pad area PA and may be connected to pad electrodes PD that are spaced apart from each other in the first direction DR1 through connection electrodes, and the like. The pad electrodes PD may be disposed on a rear surface of the display panel DP and may be electrically connected to the circuit board FCB (see FIG. 2).

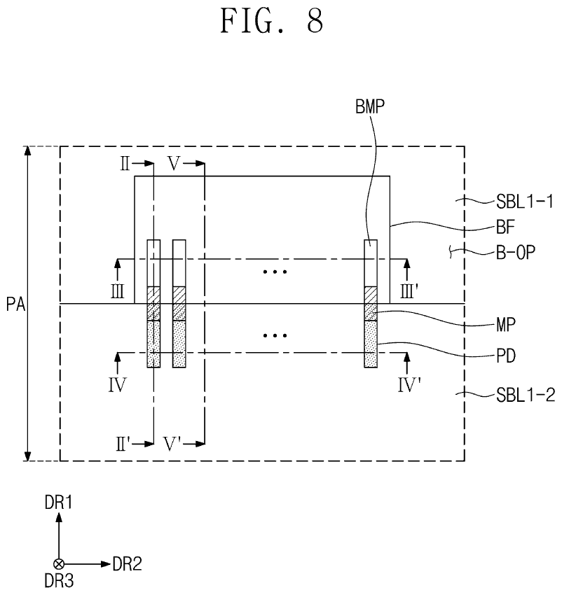

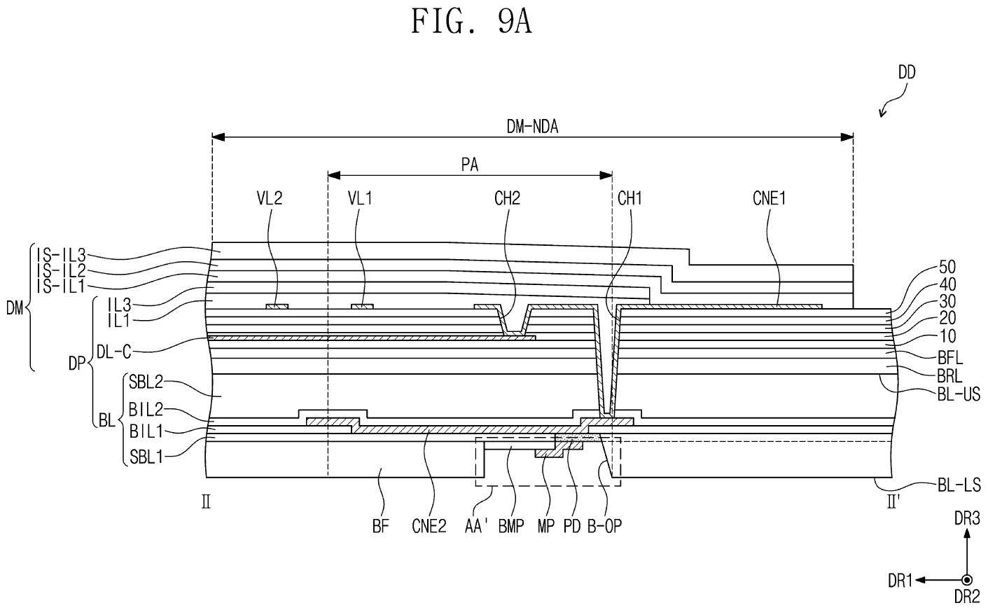

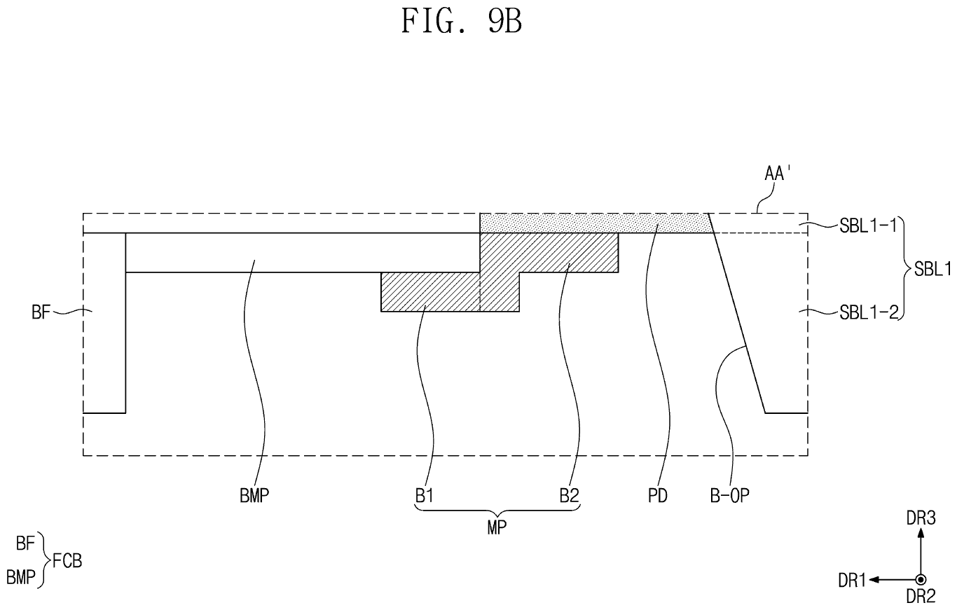

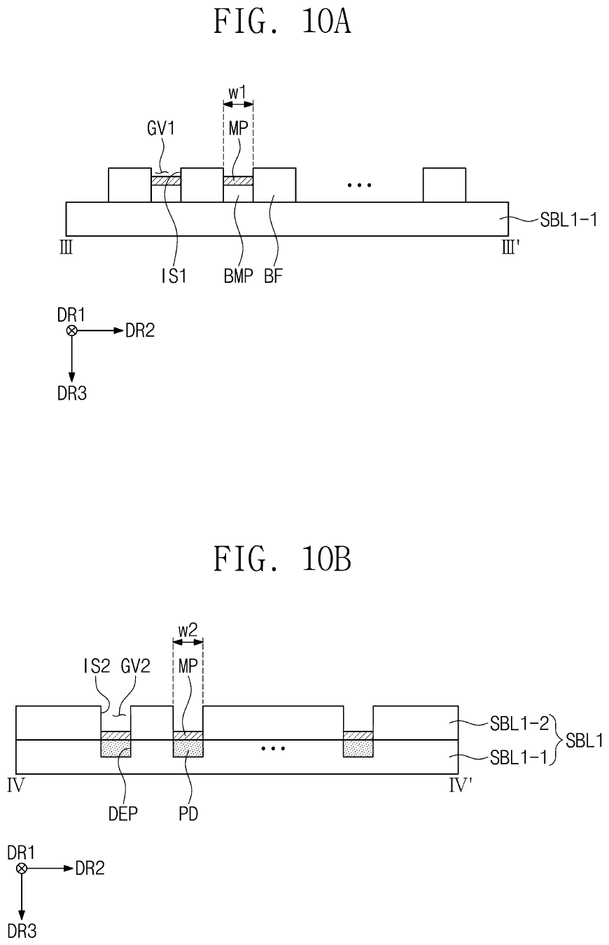

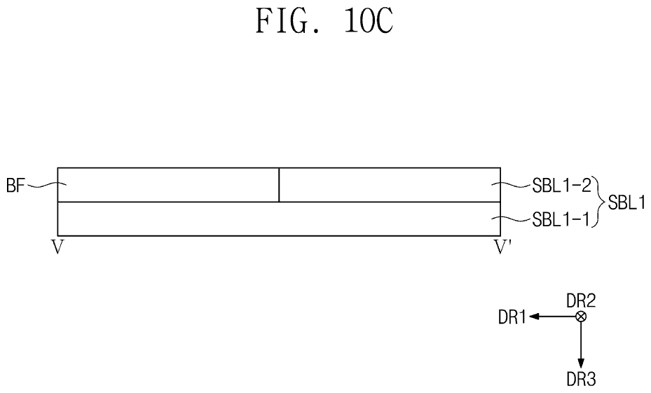

FIG. 8 is an enlarged view of a portion of a display device according to an embodiment of the present disclosure. FIG. 9A is a cross-sectional view of a display device, taken along line II-II′ of FIG. 8. FIG. 9B is an enlarged view of area AA′ illustrated in FIG. 9A. FIG. 10A is a cross-sectional view of the display device, taken along line III-III′ of FIG. 8. FIG. 10B is a cross-sectional view of a display device, taken along line IV-IV′ of FIG. 8. FIG. 10C is a cross-sectional view of a display device, taken along line V-V′ of FIG. 8. FIGS. 8 to 10C are views illustrating a state in which the circuit board FCB is attached to the display panel DP. Hereinafter, for convenience of explanation, a further description of components and technical aspects previously described will be omitted.

Referring to FIGS. 8 and 9A, the display device DD according to an embodiment of the present disclosure may include a first connection electrode CNE1 and a second connection electrode CNE2 (or, a connection electrode). The first connection electrode CNE1 is disposed on the same layer as that of the first connection pattern CNP1 illustrated in FIG. 6, and a portion of a data connection line DL-C, which overlaps the non-display area DM-NDA, is disposed on the same layer as that of the gate GT1 of the silicon transistor S-TFT of FIG. 6. The data connection line DL-C may be electrically connected to the data line DL.

The second connection electrode CNE2 may be exposed to the outside through a lower surface BL-LS of the base layer BL for back bonding with the circuit board FCB. However, the present disclosure is not limited thereto. For example, in an embodiment, the second connection electrode CNE2 is not directly exposed to the outside, but may be exposed to the outside through a contact hole, or the like. A lower surface BL-LS of the base layer BL faces an upper surface BL-US of the base layer BL in the third direction DR3.

The base layer BL may include a first sub-base layer SBL1, a first base insulating layer BIL1, a second base insulating layer BIL2, and a second sub-base layer SBL2. The first base insulating layer BIL1 is disposed on the first sub-base layer SBL1, and the second base insulating layer BIL2 is disposed on the first base insulating layer BIL1 and covers the second connection electrode CNE2. The second sub-base layer SBL2 is disposed on the second base insulating layer BIL2.

The first sub-base layer SBL1 and the second sub-base layer SBL2 may include a synthetic resin material, for example, polyimide. The first base insulating layer BIL1 and the second base insulating layer BIL2 may include an inorganic material. For example, the first base insulating layer BIL1 and the second base insulating layer BIL2 may include silicon nitride, silicon oxynitride, or silicon oxide.

The first base insulating layer BIL1 is disposed on the first sub-base layer SBL1. The first sub-base layer SBL1 may be disposed under the first base insulating layer BIL1. The first sub-base layer SBL1 provides a lower surface BL-LS of the base layer BL, and a base opening (or an opening) B-OP is defined in the first sub-base layer SBL1 to expose the second connection electrode CNE2 to the outside of the display module DM.

The second connection electrode CNE2 may be embedded in the base layer BL. However, the present disclosure is not limited thereto. For example, in an embodiment, the second connection electrode CNE2 may be disposed on the lower surface BL-LS of the base layer BL. In the base layer BL, the base opening B-OP, which will be described further below, may not be defined, even though it includes a single-layer synthetic resin layer, or may include multi-layers. The pad electrodes PD disposed on the lower surface BL-LS of the base layer BL may be connected to the conductive pattern disposed on the upper surface BL-US of the base layer BL through a contact hole that passes through the base layer BL.

The first connection electrode CNE1 may be connected to the second connection electrode CNE2 through a first contact hole CH1, and may be connected to the data connection line DL-C through a second contact hole CH2. The first contact hole CH1 and the second contact hole CH2 may be disposed in the non-display area DM-NDA. The first contact hole CH1 may be formed to pass through portions of the plurality of insulating layers 10 to 50, the barrier layer BRL, the buffer layer BFL, and the base layer BL. The first contact hole CH1 may be connected to the second connection electrode CNE2 while passing through the second base insulating layer BIL2 and the second sub-base layer SBL2 of the base layer BL. The second contact hole CH2 may be formed to pass from the second insulating layer 20 to the fifth insulating layer 50. The first connection electrode CNE1 may be connected to the data connection line DL-C through the second contact hole CH2.

The base layer BL may further include pad electrodes PD that are connected to the second connection electrode CNE2. The pad electrodes PD that contact the second connection electrode CNE2 may be exposed to the outside through the base opening B-OP defined in the first sub-base layer SBL1. For example, the pad electrodes PD may be exposed through a surface of the base layer BL, as shown in FIG. 9A. The pad electrodes PD may extend in the first direction DR1, and may be arranged in the second direction DR2. However, the shape and the disposition of the pad electrodes PD are not limited to the illustration. The pad electrodes PD may overlap the non-display area DM-NDA. For example, the pad electrodes PD may be disposed in the pad area PA.

Referring to FIGS. 9A and 9B, the first sub-base layer SBL1 may include a (1-1)-th sub-base layer SBL1-1 and a (1-2)-th sub-base layer SBL1-2. The (1-1)-th sub-base layer SBL1-1 and the (1-2)-th sub-base layer SBL1-2 may be formed integrally. The (1-1)-th sub-base layer SBL1-1 and the (1-2)-th sub-base layer SBL1-2 may include the same material. The (1-1)-th sub-base layer SBL1-1 may be a portion that is formed by etching the (1-2)-th sub-base layer SBL1-2. A base opening B-OP that exposes the pad electrodes PD to the outside of the display module DM may be defined in the (1-2)-th sub-base layer SBL1-2. A thickness of the (1-2)-th sub-base layer SBL1-2 may be greater than a thickness of the (1-1)-th sub-base layer SBL1-1.

As illustrated in FIG. 3, the circuit board FCB may be attached to the display panel DP in a state in which it is bent on a rear surface of the display panel DP. An adhesion layer may be disposed between the circuit board FCB and the lower surface BL-LS of the base layer BL. The circuit board FCB may be fixed to the lower surface BL-LS of the base layer BL by the adhesion layer. The circuit board FCB may be disposed directly on the (1-1)-th sub-base layer SBL1-1. As illustrated in FIG. 9A, the circuit board FCB may be directly attached to the (1-1)-th sub-base layer SBL1-1 without being bent in the pad area PA.

Referring to FIGS. 3, 9A, and 9B, according to embodiments of the present disclosure, the circuit board FCB may include a base film BF, and a plurality of bump electrodes BMP that contact the base film BF. The base film BF may be formed integrally, and may be electrically connected to the plurality of bump electrodes BMP. In this case, the base film BF may include a plurality of wiring lines. However, the present disclosure is not limited thereto. For example, according to embodiments, the base film BF may be attached only to the plurality of bump electrodes BMP and is not electrically connected thereto. In this case, the base film BF may include a synthetic resin material, for example, polyimide. According to an embodiment, the bump electrodes BMP may be disposed under the base film BF.

Still referring to FIGS. 3, 9A, and 9B, according to embodiments of the present disclosure, the circuit board FCB may include the base film BF along with the multiple bump electrodes BMP that make contact with the base film BF. The base film BF can be formed as a single integrated structure, and it may be electrically connected to the bump electrodes BMP through embedded wiring lines. In embodiments, however, the base film BF might only serve as a physical attachment to the bump electrodes BMP, without any electrical connection to them. In such cases, the base film BF may be made from a synthetic resin material, such as polyimide, which provides structural support. Additionally, in an embodiment, the bump electrodes BMP are positioned beneath the base film BF.

Referring to FIGS. 8 to 9B, in an embodiment, the bump electrodes BMP do not overlap the pad electrodes PD on a plane. However, the present disclosure is not limited thereto. For example, in an embodiment, the bump electrodes BMP may partially overlap the pad electrodes PD on a plane. In this case, the bump electrodes BMP may directly contact the pad electrodes PD. The bump electrodes BMP may be disposed in correspondence to the pad electrodes PD. That is, one bump electrode BMP may correspond to one pad electrode PD. The bump electrodes BMP may extend in the first direction DR1, and may be disposed in the second direction DR2. According to an embodiment, an extent of the pad electrodes PD on a plane may be greater than an extent of the bump electrodes BMP on a plane.

According to embodiments, the bump electrodes BMP may be positioned such that they do not overlap the pad electrodes PD on the same plane. However, the present disclosure is not limited thereto. For example, in some embodiments, the bump electrodes BMP may partially overlap the pad electrodes PD on the plane, allowing for direct contact between them. Each bump electrode BMP may be positioned to correspond with a specific pad electrode PD, meaning that there is a one-to-one correspondence between them. The bump electrodes BMP may extend along the first direction DR1 and are arranged in the second direction DR2. In an embodiment, the surface area covered by the pad electrodes PD on the plane may be larger than the area covered by the bump electrodes BMP on the plane.

The bump electrodes BMP may be electrically connected to the pad electrodes PD. For example, the display device DD (see FIG. 2) according to embodiments of the present disclosure may further include metal patterns MP that electrically connect the bump electrodes BMP and the pad electrodes PD. The metal patterns MP may be disposed on the pad electrodes PD and the bump electrodes BMP to electrically connect the pad electrodes PD and the bump electrodes BMP. The metal patterns MP, a number of which corresponds to the pad electrodes PD and bump electrodes BMP, respectively, may be provided.

For example, in the display device DD according to embodiments of the present disclosure (see FIG. 2), metal patterns MP may be utilized to facilitate this electrical connection. These metal patterns MP may be positioned on both the pad electrodes PD and the bump electrodes BMP, creating a conductive link between them. A set of metal patterns MP, corresponding in number to the pad electrodes PD and bump electrodes BMP, may be provided, which may facilitate reliable connections in the device.

Each of the metal patterns MP may be a pattern in which metal ink is cured. The metal patterns MP may include solder paste. The metal patterns MP may be formed of metal ink including, for example, silver, copper, or the like. The metal patterns MP may be disposed on the pad electrode PD exposed by the base opening B-OP, respectively. The metal patterns MP may be formed by curing and patterning the metal ink. The metal patterns MP may be formed at a low temperature, and the pad electrodes PD and the bump electrodes BMP may be electrically connected to each other and bonded to each other at the same time without a process of pressing at a high temperature.

Referring to FIG. 10A, a first groove GV1 may be defined in the base film BF. A plurality of first grooves GV1 may be provided. According to an embodiment of the present disclosure, the bump electrodes BMP may be disposed in the plurality of first grooves GV1, respectively. The bump electrodes BMP may be exposed to the outside by the plurality of first grooves GV1, respectively.

Referring to FIG. 10B, a recessed part DEP may be defined in a (1-1)-th sub-base layer SBL1-1, and a second groove GV2 may be defined in a (1-2)-th sub-base layer SBL1-2. In the present disclosure, the (1-1)-th sub-base layer SBL1-1 may be referred to as a first sub-base layer, and the (1-2)-th sub-base layer SBL1-2 may be referred to as a second sub-base layer. The recessed part DEP and the second groove GV2 may be provided in plural numbers, respectively. According to an embodiment of the present disclosure, the pad electrodes PD may be disposed in the plurality of recessed parts DEP, respectively, and the pad electrodes PD may be exposed to the outside by the plurality of second grooves GV2, respectively.

Referring to FIGS. 8 to 10B, the plurality of first grooves GV1 and the plurality of second grooves GV2 may be formed to correspond to each other. That is, one first groove GV1 of the plurality of first grooves GV1 and one second groove GV2, among the plurality of second grooves GV2, may be formed to correspond to each other with respect to the first direction DR1. Each of the plurality of first grooves GV1 may have a first width w1, and each of the plurality of second grooves GV2 may have a second width w2. According to an embodiment of the present disclosure, the first width w1 and the second width w2 may be about equal to each other. However, the present disclosure is not limited thereto. For example, according to embodiments, the second width w2 may be greater than the first width w1. According to an embodiment of the present disclosure, the depth of each of the plurality of first grooves GV1 in the third direction DR3 and the depth of each of the plurality of second grooves GV2 in the third direction DR3 may be about equal to each other. However, the present disclosure is not limited thereto. For example, according to embodiments, the depth of each of the plurality of first grooves GV1 in the third direction DR3 and the depth of each of the plurality of second grooves GV2 in the third direction DR3 may be different from each other.

According to an embodiment of the present disclosure, the metal patterns MP may include a first part B1 disposed in the plurality of first grooves GV1 and a second part B2 disposed in the plurality of second grooves GV2. The first part B1 and the second part B2 may be formed integrally. The first part B1 may be disposed on the bump electrodes BMP, and the second part B2 may be disposed on the pad electrodes PD. The first part B1 may be electrically connected to the bump electrodes BMP, and the second part B2 may be electrically connected to the pad electrodes PD. As a result, the bump electrodes BMP and the pad electrodes PD may be electrically connected to each other.

The first part B1 may contact a first inner surface IS1 that defines the plurality of first grooves GV1, and the second part B2 may contact a second inner surface IS2 that defines the plurality of second grooves GV2. Each of the metal patterns MP may be disposed in one of the plurality of first grooves GV1 and one of the plurality of second groove GV2, which corresponds to the one first groove GV1. Each of the plurality of first grooves GV1 and the plurality of second grooves GV2 may serve as a dam so that the metal patterns MP disposed in the second direction DR2 may be insulated from each other. As a result, electrical failures that may occur when adjacent metal patterns MP are short-circuited may be prevented.

Furthermore, the plurality of bump electrodes BMP may be disposed in the plurality of first grooves GV1 defined in the base film BF so that the plurality of bump electrodes BMP may be prevented from being bent leftward and rightward (for example, in the second direction DR2) during the process of attaching the circuit board FCB on the rear surface of the display panel DP. As a result, embodiments may prevent defects due to misalignment between the plurality of bump electrodes BMP and the plurality of pad electrodes PD. For example, the arrangement according to embodiments of the present disclosure may contribute to stabilizing the bump electrodes BMP, preventing them from bending sideways (e.g., in the second direction DR2) during the attachment process of the circuit board FCB to the rear surface of the display panel DP. Such a configuration may reduce the risk of misalignment between the bump electrodes BMP and the pad electrodes PD, thereby reducing the likelihood of assembly defects.

Referring to FIG. 10C, a thickness of the base film BF and a thickness of the (1-2)-th sub-base layer SBL1-2 may be the same. However, the present disclosure is not limited thereto. For example, according to embodiments, the thickness of the base film BF and the thickness of the (1-2)-th sub-base layer SBL1-2 may be different. For example, the thickness of the (1-2)-th sub-base layer SBL1-2 may be greater than the thickness of the base film BF. In an embodiment, the (1-2)-th sub-base layer SBL1-2 may be omitted.

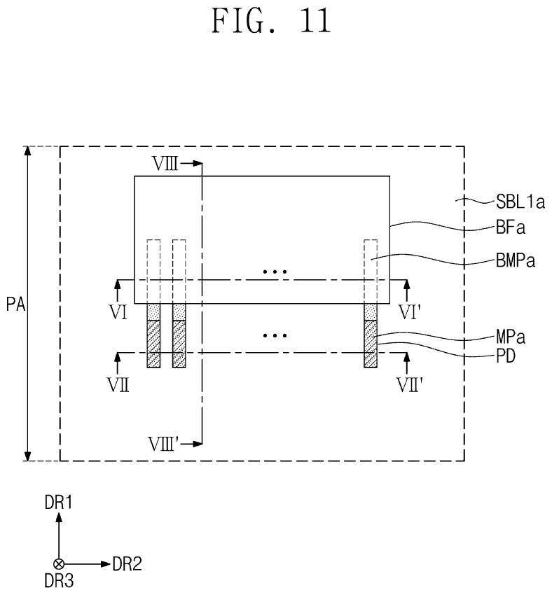

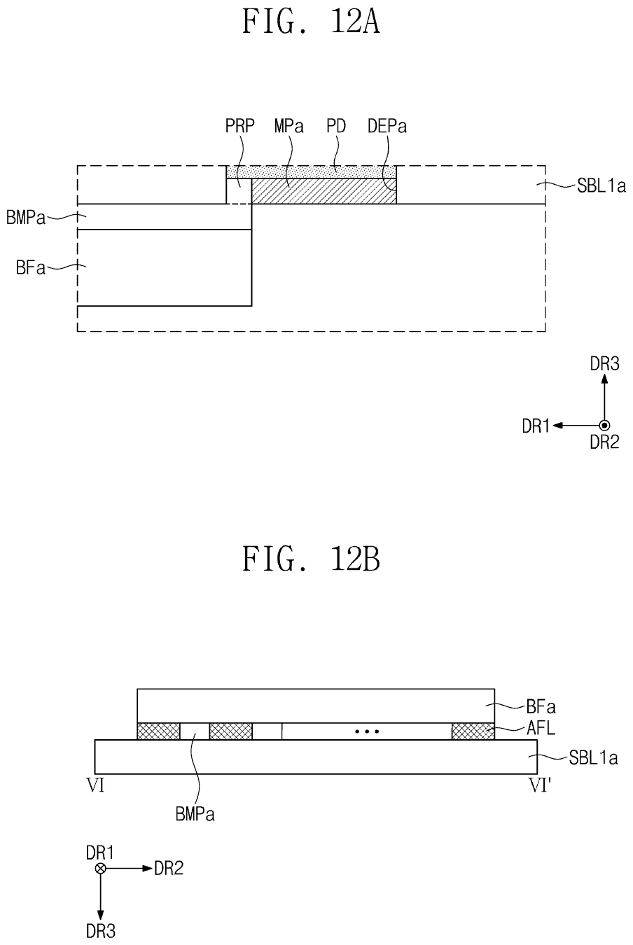

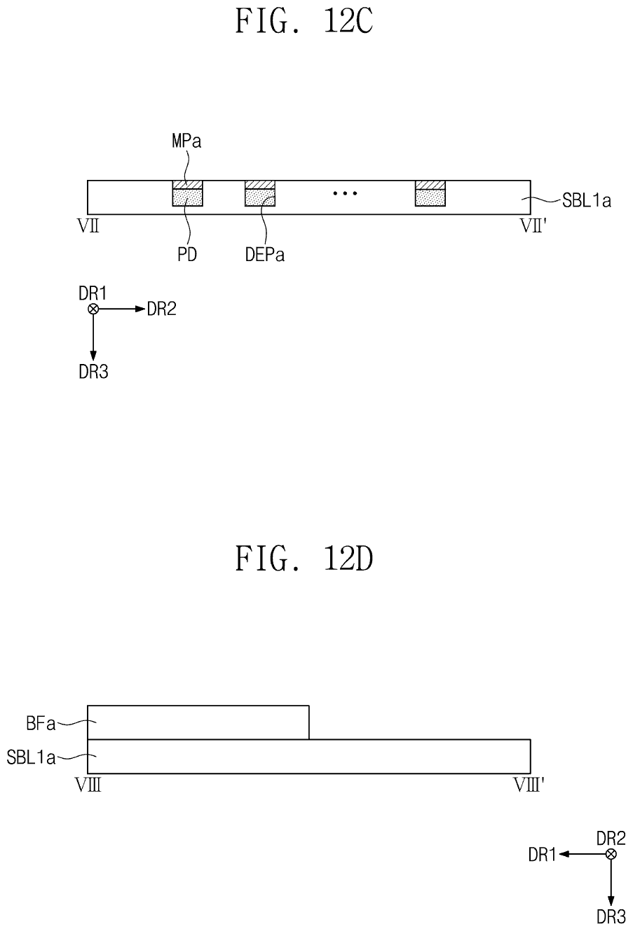

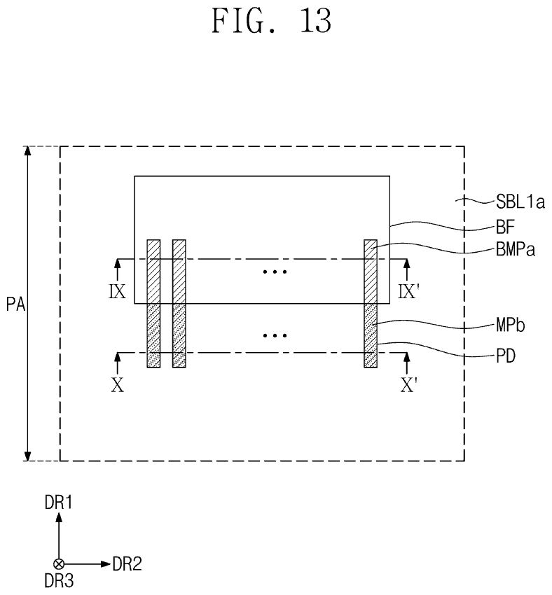

FIG. 11 is an enlarged view of a portion of a display device according to an embodiment of the present disclosure. FIG. 12A is an enlarged cross-sectional view of a portion of a display device according to an embodiment of the present disclosure. FIG. 12B is a cross-sectional view of the display device, taken along line VI-VI′ of FIG. 11. FIG. 12C is a cross-sectional view of the display device, taken along line VII-VII′ of FIG. 11. FIG. 12D is a cross-sectional view of the display device, taken along line VIII-VIII′ of FIG. 11. FIG. 12A is a cross-sectional view corresponding to FIG. 9B. For convenience of explanation, a further description components and technical aspects previously described will be omitted.

Referring to FIGS. 11 to 12D, a plurality of recessed parts DEPa may be defined in the first sub-base layer SBL1a, and pad electrodes PD may be disposed in each of the plurality of recessed parts DEP. According to an embodiment of the present disclosure, the depth of each of the plurality of recessed parts DEPa may be greater than the thickness of each of the pad electrodes PD in the third direction DR3. Metal patterns MPa may be disposed on the plurality of recessed parts DEPa. The metal patterns MPa may contact an inner surface that defines the plurality of recessed parts DEPa. The metal patterns MPa may be disposed directly on the pad electrodes PD. A sum of a thickness of the pad electrodes PD in a third direction DR3 and a thickness of the metal patterns MPa in the third direction DR3 may be the same as a depth of the plurality of recessed parts DEPa. However, the present disclosure is not limited thereto. For example, according to embodiments, a sum of the thickness of the pad electrodes PD in the third direction DR3 and the thickness of the metal patterns MPa in the third direction DR3 may be less than the depths of the plurality of recessed parts DEPa.

According to an embodiment of the present disclosure, each of the bump electrodes BMPa may include a protrusion PRP. The protrusion PRP may extend from the bump electrodes BMPa in the third direction DR3. The bump electrodes BMPa and the protrusions PRP may be formed integrally. The protrusion PRP may partially overlap the pad electrodes PD on a plane. In this case, the protrusion PRP may directly contact the pad electrodes PD. In an embodiment, the protrusion PRP does not contact the pad electrodes PD. In this case, an empty space may be defined between the protrusion PRP and the pad electrodes PD.

According to an embodiment of the present disclosure, the protrusion PRP may contact an inner surface that defines the plurality of recessed parts DEPa. Furthermore, the protrusion PRP may directly contact the metal patterns MPa. The bump electrodes BMPa may be electrically connected to the pad electrodes PD through the protrusions PRP. However, the bump electrodes BMPa may be electrically connected to the pad electrodes PD through the metal patterns MPa that directly contact the protrusions PRP and the pad electrodes PD. When the bump electrodes BMPa are electrically connected to the pad electrodes PD through the metal patterns MPa, a resistance to a flowing current may be reduced. As a result, efficient electrical characteristics may be maintained, compared to a case in which the bump electrodes BMPa are directly electrically connected to the pad electrodes PD through the protrusion PRP.

In an embodiment, the protrusion PRP may come into contact with an inner surface that defines the recessed parts DEPa and may also make direct contact with the metal patterns MPa. The bump electrodes BMPa can be electrically connected to the pad electrodes PD through these protrusions PRP. In an embodiment, the bump electrodes BMPa may connect to the pad electrodes PD via the metal patterns MPa, which directly contact both the protrusions PRP and the pad electrodes PD. Using the metal patterns MPa as an intermediary for this connection can reduce resistance to current flow, allowing for more efficient electrical characteristics compared to a direct connection between the bump electrodes BMPa and pad electrodes PD through the protrusions PRP alone.

Furthermore, because the protrusions PRP are disposed on the plurality of recessed parts DEPa before forming the metal patterns MPa, embodiments may prevent defects due to misalignment of the bump electrodes BMPa and the pad electrodes PD.

Referring to FIG. 12B, an adhesion layer AFL may be disposed between the base film BFa and the first sub-base layer SBL1a. The adhesion layer AFL may not overlap the bump electrodes BMPa and may be disposed between the bump electrodes BMPa. However, the present disclosure is not limited thereto. For example, in an embodiment, the adhesion layer AFL may overlap the bump electrodes BMPa and may be disposed between the bump electrodes BMPa and the first sub-base layer SBL1a. According to an embodiment of the present disclosure, the adhesion layer AFL may include a non-conductive material. For example, the adhesion layer AFL may include a non-conductive film.

Referring to FIG. 12D, compared to FIG. 10C, the (1-2)-th sub-base layer SBL1-2 may be omitted. The base film BFa and the bump electrodes BMPa (see FIG. 11) of an embodiment of the present disclosure may be directly disposed on the first sub-base layer SBL1a without being bent.

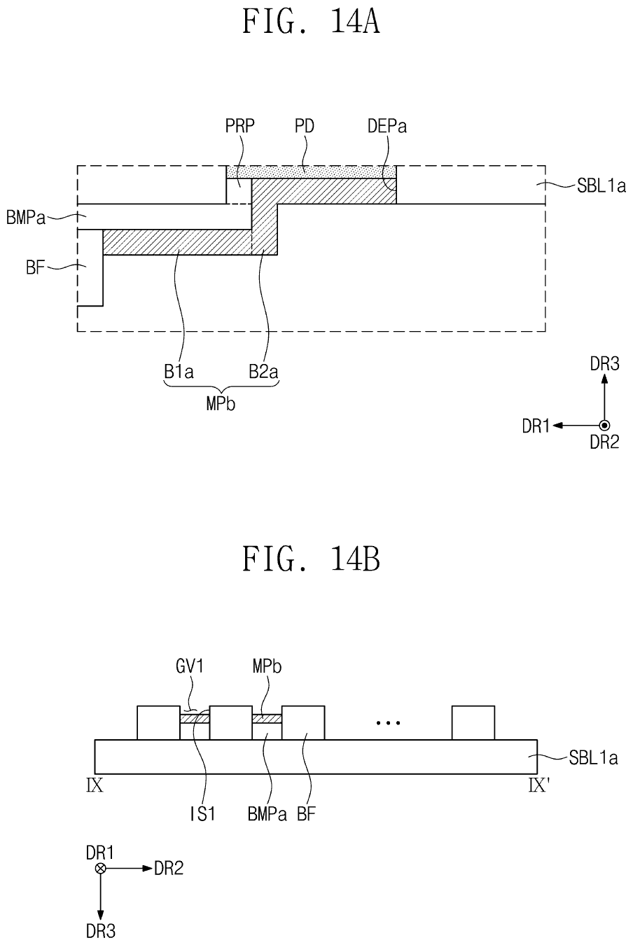

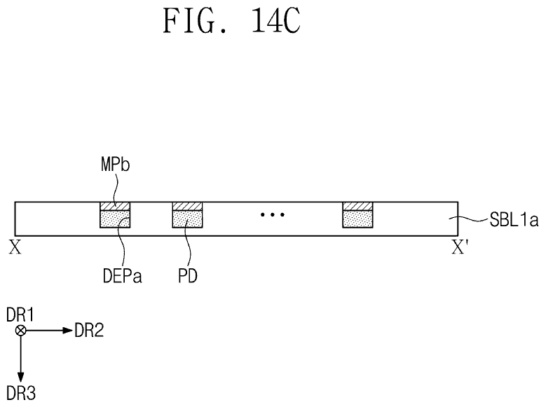

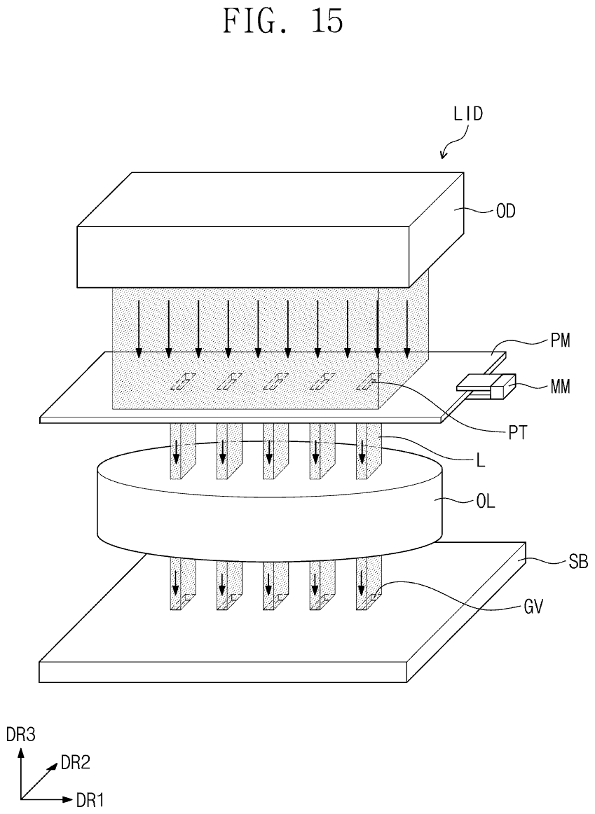

FIG. 13 is an enlarged view of a portion of a display device according to an embodiment of the present disclosure. FIG. 14A is an enlarged cross-sectional view of a portion of a display device according to an embodiment of the present disclosure. FIG. 14B is a cross-sectional view of a display device, taken along line IX-IX′ of FIG. 13. FIG. 14C is a cross-sectional view of a display device, taken along line X-X′ of FIG. 13.

Referring to FIGS. 13 to 14C, the metal patterns MPb may include first parts B1a that are disposed in the plurality of first grooves GV1, respectively, and second parts B2a that disposed in the plurality of recessed parts DEPa, respectively. The first part B1a and the second part B2a may be formed integrally. The first parts B1a may be disposed on the bump electrodes BMPa, and the second parts B2a may be disposed on the pad electrodes PD. The first parts B1a may be electrically connected to the bump electrodes BMP, respectively, and the second parts B2a may be electrically connected to the pad electrodes PD, respectively. As a result, the bump electrodes BMPa and the pad electrodes PD may be electrically connected to each other.

Each of the metal patterns MPb may be disposed in one of the plurality of first grooves GV1 and one of the plurality of recessed parts DEPa, which corresponds to the one first groove GV1. Each of the plurality of first grooves GV1 and the plurality of recessed parts DEPa may serve as a dam to insulate the metal patterns MPb from each other. As a result, an electrical failure when the metal patterns MPb are short-circuited may be prevented.

The metal patterns MPb may be disposed to cover the entire bump electrodes BMPa and pad electrodes PD exposed to the outside. Because the metal patterns MPb are disposed to contact the entire bump electrodes BMPa and pad electrodes PD, a resistance to a flowing current may be reduced. As a result, efficient electrical characteristics may be maintained when the bump electrodes BMPa are electrically connected to the pad electrodes PD through the metal patterns MPa.

For example, the metal patterns MPb may be positioned to cover the entirety of the bump electrodes BMPa and pad electrodes PD exposed to the outside. By fully contacting both the bump electrodes BMPa and pad electrodes PD, these metal patterns MPb help reduce current resistance. This arrangement may enables efficient electrical performance when the bump electrodes BMPa are electrically connected to the pad electrodes PD through the metal patterns MPb.

FIG. 15 is a perspective view of a laser irradiating device used to manufacture a display device according to an embodiment of the present disclosure.

Referring to FIG. 15, a laser irradiating device LID may include an optical system OD that emits a laser L, a pattern mask PM, to which the laser L emitted from the optical system OD is input, and which includes a plurality of patterns PT, through which the laser L passes, and an optical lens OL. The laser L may be directed to a substrate SB through a laser irradiating device LID according to an embodiment of the present disclosure. The optical system OD may be positioned above the laser irradiating device LID, and the pattern mask PM may be disposed below the optical system OD. An optical lens OL may be disposed between the pattern mask PM and the substrate SB. The substrate SB may be the base film BF or a (1-2)-th sub-base layer SBL1-2 illustrated in FIGS. 8 to 10C. That is, the laser irradiating device LID may be a device for forming a plurality of first grooves GV1 in the base film BF or forming a plurality of second grooves GV2 in the (1-2)-th sub-base layer SBL1-2, through the laser L.

The optical system OD may emit the laser L. The wavelength of the laser L may be about 200 nm or more and about 400 nm or less. For example, the wavelength of the laser L may be about 248 nm or more and about 266 nm or less in an embodiment. However, the present disclosure is not limited thereto.

The pattern mask PM may receive the laser L emitted from the optical system OD. According to an embodiment of the present disclosure, the laser L emitted from the optical system OD and input to the pattern mask PM may include a laser line beam. However, the present disclosure is not limited thereto. For example, according to embodiments, the laser L may include a laser area beam. Furthermore, the laser L itself emitted by the light source may include a laser line beam.

Because the pattern mask PM may be damaged by the laser L directed onto the pattern mask PM, it may have a processing threshold that is greater than a specific size. For example, the pattern mask PM may have a processing threshold that is about 100 mJ/cm² or more.

The pattern mask PM may include a plurality of patterns PT. The plurality of patterns PT may be disposed to overlap a plurality of grooves GV on a plane. The plurality of patterns PT may extend in the second direction DR2 and may be disposed in the first direction DR1. The sizes of the plurality of patterns PT may be the same, and intervals between adjacent patterns PT may also be the same. The plurality of grooves GV may correspond to the plurality of first grooves GV1 or the plurality of second grooves GV2 illustrated in FIGS. 8 to 10C. The patterned laser L may form the plurality of grooves GV in the substrate SB, respectively. The shapes and sizes of the plurality of grooves GV may be the same.

The laser irradiating device LID according to embodiments of the present disclosure may further include a movement module MM that moves the pattern mask PM in the third direction DR3. While the laser L is directed to the substrate SB, the movement module MM may move the pattern mask PM in the third direction DR3. Accordingly, as the pattern mask PM moves in the third direction DR3, an extent of the patterned laser L that passes through the pattern mask PM may gradually increase. As a result, the extent of the plurality of grooves GV may be controlled.

An optical lens OL may be disposed between the pattern mask PM and the substrate SB. The optical lens OL may condense the laser L that passes through the pattern mask PM. That is, the optical lens OL may include a convex lens. According to an embodiment of the present disclosure, the optical lens OL may include a chromatic aberration lens. For example, the optical lens OL may be a lens that is set such that chromatic aberration does not occur. As a result, the laser L that passes through the optical lens OL may be uniformly irradiated to the substrate SB.

The display device according to embodiments of the present disclosure may include the base film, in which a plurality of grooves are defined, and bump electrodes disposed in the plurality of grooves. The metal patterns that electrically connect the bump electrodes and the metal patterns may be in the plurality of grooves so that the metal patterns may be insulated from each other. As a result, electrical failures caused when the metal patterns are short-circuited may be prevented.

In addition, because the bump electrodes may be disposed in the plurality of grooves, the bump electrodes may be prevented from being bent in one direction during the process of attaching the circuit board to the rear surface of the display panel. As a result, defects due to misalignment between the bump electrodes and the pad electrodes may be prevented.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a base layer including a plurality of pad electrodes exposed through a surface of the base layer;
a circuit board including a plurality of bump electrodes disposed on the base layer, and a base film in which a plurality of first grooves that expose the plurality of bump electrodes through the surface of the base layer are defined; and
a plurality of metal patterns electrically connecting the plurality of pad electrodes and the plurality of bump electrodes,
wherein each of the plurality of metal patterns includes:
a first part disposed in the plurality of first grooves; and
a second part disposed on the plurality of pad electrodes.

2. The display device of claim 1, wherein the base layer includes:
a first sub-base layer in which a plurality of recessed parts are defined, wherein the plurality of pad electrodes are disposed in the plurality of recessed parts; and
a second sub-base layer in which a plurality of second grooves that expose the plurality of pad electrodes are defined.

3. The display device of claim 2, wherein the second part is disposed in the plurality of second grooves.

4. The display device of claim 3, wherein the second sub-base layer includes an inner surface that defines the plurality of second grooves, and
wherein the second part contacts the inner surface.

5. The display device of claim 2, wherein the base film includes an inner surface that defines the plurality of first grooves, and
wherein the first part contacts the inner surface.

6. The display device of claim 2, wherein a width of each of the plurality of first grooves is about equal to a width of each of the plurality of second grooves.

7. The display device of claim 2, wherein a depth of each of the plurality of first grooves in a thickness direction of the second sub-base layer is about equal to a depth of each of the plurality of second grooves in the thickness direction.

8. The display device of claim 2, wherein the base film is disposed directly on the second sub-base layer.

9. The display device of claim 2, further comprising:
an adhesion layer disposed between the base film and the second sub-base layer.

10. The display device of claim 1, wherein a plurality of recessed parts, in which the plurality of pad electrodes are disposed, are defined in the base layer, and a depth of each of the plurality of recessed parts is greater than a thickness of each of the plurality of pad electrodes.

11. The display device of claim 10, wherein each of the plurality of bump electrodes includes a protrusion that protrudes toward the plurality of recessed parts, and
wherein each protrusion contacts an inner surface that defines a corresponding one of the plurality of recessed parts.

12. The display device of claim 11, wherein each protrusion directly contacts a corresponding one of the plurality of pad electrodes.

13. The display device of claim 10, wherein the first part is disposed in the plurality of first grooves, and
wherein the second part is disposed in the plurality of recessed parts.

14. The display device of claim 13, wherein the second part contacts an inner surface that defines the plurality of recessed parts.

15. The display device of claim 1, further comprising:
a circuit layer disposed on the base layer, and including at least one signal line electrically connected to at least one of the pad electrodes.

16. A display device, comprising:
a base layer including a plurality of pad electrodes exposed through a surface of the base layer,
wherein a plurality of recessed parts, in which the plurality of pad electrodes are disposed, are defined in the base layer;
a circuit board including a plurality of bump electrodes disposed on the base layer, and a base film disposed on the plurality of bump electrodes; and
a plurality of metal patterns electrically connecting the plurality of pad electrodes and the plurality of bump electrodes, and disposed in the plurality of recessed parts,
wherein each of the plurality of bump electrodes includes a protrusion that protrudes toward a corresponding one of the plurality of recessed parts.

17. The display device of claim 16, wherein a depth of each of the plurality of recessed parts is greater than a thickness of each of the plurality of pad electrodes, and
wherein the protrusion contacts an inner surface that defines the plurality of recessed parts.

18. The display device of claim 17, wherein a plurality of first grooves that expose the plurality of bump electrodes through the surface of the base layer are defined in the base film.

19. The display device of claim 18, wherein each of the plurality of metal patterns includes:
a first part disposed in the plurality of first grooves; and
a second part disposed in the plurality of recessed parts.

20. An electronic device, comprising:
a housing;
an electronic module disposed inside the housing; and
a display device that overlaps the electronic module,
wherein the display device includes:
a base layer including a plurality of pad electrodes exposed through a surface of the base layer;
a circuit board including a plurality of bump electrodes disposed on the base layer, and a base film in which a plurality of grooves that expose the plurality of bump electrodes through the surface of the base layer are defined; and
a plurality of metal patterns electrically connecting the plurality of pad electrodes and the plurality of bump electrodes,
wherein each of the plurality of metal patterns includes:
a first part disposed on the plurality of bump electrodes; and
a second part disposed on the plurality of pad electrodes.
